(19) United States
(12) Patent Application Publication
(10) Pub. No.: US 2008/0290376 A1
(43) Pub. Date: Nov. 27, 2008

(54) Semiconductor Integrated Circuit

(76) Inventor: Junichi Yano, Osaka (JP)

Correspondence Address: MCDERMOTT WILL & EMERY LLP, 600 13TH STREET, NW, WASHINGTON, DC, 20005-3096, US

(21) Appl. No.: 11/666,760

(22) PCT Filed: Oct. 28, 2005
(86) PCT No.: PCT/JP05/19888

§ 371 Date: Feb. 11, 2008

(30) Foreign Application Priority Data
Nov. 2, 2004 (JP) 2004-319149

(51) Int. Cl. H01L 29/00; G06F 9/45

(52) U.S. Cl. 257/208; 716/7; 257/E29.001

(57) ABSTRACT

[The problems] In a semiconductor integrated circuit in which tilted wiring is used, the tilted wiring cannot be used effectively since the arrangement of blocks is restricted.

[Means for solving] In the semiconductor integrated circuit consisting of at least a first block, a second block and a third block, the third block B5 is diagonally arranged between the first bock B1 and the second block B2 at a predetermined angle of approximately 45 degrees to the both blocks, the first block B1 includes at least a first output P1, the second block B2 includes at least a first input pin P2, the third block B5 includes at least a second input pin Q1 and a second output pin Q2, the first output pin P1 and the second input pin Q1 are connected by a first wiring L1, and the second output pin Q2 and the first input pin P2 are connected by a second wiring L2. Herewith, the degree of integration can be increased and the tilted wiring can be effectively used.

### TECHNICAL FIELD

The present invention relates to semiconductor integrated circuits, cells and methods of designing the semiconductor integrated circuit, in particular, to an improvement technique in using a tilted wiring.

### BACKGROUND ART

In conventional semiconductor integrated circuits, in particular, in a semiconductor integrated circuit using cells such as standard cells and gate array cells, a configuration of stacking the wiring layers so as to be orthogonal to each other has been widely adopted for the multi-layer wiring configuration thereof. For instance, in the case of four-layer wiring configuration, first and third wirings are arranged in the X direction, and second and fourth wirings are arranged in the Y direction. In such configuration, the wiring of a length of greater than or equal to <2 times of the shortest distance is required to connect two points spaced apart in the diagonal direction of 45 degrees.

Recently, delay of the circuit resulting from an increase in the wiring length has become a large problem. Consequently, a technique of using a tilted wiring that forms an angle of 45 degrees to the X, Y directions at one part of the multi-layer wiring configuration has been proposed. A wiring configuration of the semiconductor integrated circuit shown in FIG. 12 is disclosed in patent document 1 as an example. In FIG. 12, G1 to G4 are wiring grids of the first to the fourth layers, and the wiring of each layer is carried out on such wiring grids. The wirings of the third and the fourth layers are tilted wirings. The semiconductor integrated circuit in which the wiring length is optimized is thereby configured.

In patent document 1, a method of designing a semiconductor integrated circuit in relation to the insertion of repeater cells using tilted wiring is also addressed. The procedures for inserting the repeater cell are shown in FIGS. 13(a) to (d). In FIG. 13, B21 and B22 are cells, B23 is a repeater cell, and L21 to L23 are tilted wirings. The repeater cell is an element that is inserted to suppress such difficulty so as to restore the signal propagation when signal propagation becomes difficult due to reasons of circuit delay and the like.

First, the wiring between the cells B21, B22 is carried out only with the wirings in the X, Y directions, as shown in FIG. 13(d). Next, insertion of the repeater cell and the tilted wiring is carried out, as necessary, to obtain the layouts shown in FIGS. 13(a) to (c).

Patent document 1: Japanese Unexamined Patent Publication No. 2000-82743 (pp. 7-9, FIGS. 1 and 4)

### DISCLOSURE OF THE INVENTION

### Problem to be Solved by the Invention

However, in the semiconductor integrated circuit described in patent document 1 that uses tilted wirings, cells and blocks are arranged along the X, Y directions, and improvement regarding the arrangement of the cells and blocks has not been mentioned. Furthermore, consideration has not been made with respect to an effective use of the tilted wiring by improving the arrangement.

Moreover, the first wiring is restricted to X, Y directions in the method of designing the semiconductor integrated circuit in relation to the insertion of the repeater cell described in patent document 1. Consequently, a suitable wiring result using the tilted wiring is not obtained, and even the repeater cell, that is due to be unnecessary if the tilted wiring is used, must be inserted. Furthermore, the wiring correction area increases since the wiring paths before insertion and after insertion of the repeater cell greatly change, whereby re-wiring also including the surrounding wirings becomes necessary.

It is an object of the present invention to improve the arrangement of the cells and blocks in the semiconductor integrated circuit using the tilted wiring and to use the tilted wiring effectively as a result of improvement in the arrangement.

Another object is to provide a method of designing the semiconductor integrated circuit that suppresses the necessity of re-wiring to a minimum in before insertion and after insertion of the repeater cell.

### Means for Solving the Problem

A semiconductor integrated circuit of the present invention relates to a semiconductor integrated circuit configured at least by a first block, a second block and a third block; wherein the third block is obliquely arranged between the first block and the second block at a predetermined angle of approximately 45 degrees to the first block and the second block.

Herewith, the degree of freedom in the arrangement of the blocks increases, and higher integration is achieved.

In the above configuration, the case is included that the first block has at least a first output pin; the second block has at least a first input pin; the third block has at least a second input pin and a second output pin; the first output pin and the second input pin are connected by a first wiring; and the second output pin and the first input pin are connected by a second wiring.

In this case, the wiring length of the first wiring and the second wiring between the blocks is further reduced.

In the above configuration, it is preferable that at least one part of the first wiring and the second wiring respectively includes a wiring portion having a predetermined angle of approximately 45 degrees.

In this case, the wiring length is further reduced through using a tilted wiring for the first wiring and the second wiring between the blocks.

In the above configuration, it is included that the first wiring and the second wiring are made up of a substantially straight wiring.

In the above configuration, it is included that the first wiring and the second wiring are on the same straight line.

In this case, through using the tilted wiring for the first wiring and the second wiring between the blocks, and being further made to a linear shape, the wiring length is further reduced.

In the above configuration, it is included that the third block includes at least one cell; the second input pin is connected to an input pin of the cell; and the second output pin is connected to an output pin of the cell.

In the above configuration, it is included that the cell is a buffer.

In this case, a block including a repeater buffer or other cells may be further applied, and the wiring length can be reduced through inserting the repeater buffer and the like.

Further, it is included that the cell includes at least one input pin and one output pin, and the input pin and the output pin are lined in a straight line in the X direction or the Y direction.

In this case, the input pin and the output pin are on one straight line in the diagonal direction when the cell is arranged at a predetermined angle of approximately 45 degrees, whereby the cell can be easily inserted while suppressing the change in wiring to a minimum to the tilted wiring, and the wiring length is reduced also as the semiconductor integrated circuit.

The case is included that the cell has at least one input pin and one output pin, and the input pin and the output pin are arranged on a straight line having a predetermined angle of approximately 45 degrees.

In the above configuration, in a semiconductor integrated circuit consisting of at least a first block, a second block, and a third block; there is the case that the third block is arranged between the first block and the second block; and the third block includes a cell in which the input pin and the output pin are arranged on a straight line having a predetermined angle of approximately 45 degrees.

In the above configuration, it is included that the first block has at least a first output pin; the second block has at least a first input pin; the third block has at least a second input pin and a second output pin; the first output pin and the second input pin are connected by a first wiring; the second output pin and the first input pin are connected by a second wiring; the second input pin is connected to the input pin of the cell; and the second output pin is connected to the output pin of the cell.

Further, in the above configuration, it is included that the first wiring and the second wiring are made up a wiring in alignment having a predetermined angle of approximately 45 degrees respectively.

In this case, the input pin and the output pin of the cell are on one straight light in the diagonal direction, whereby the cell can be easily inserted while suppressing the change in wiring to a minimum with respect to the tilted wiring, and the wiring length is reduced also as the semiconductor integrated circuit.

A method of designing a semiconductor integrated circuit of the present invention relates to a method of designing the semiconductor integrated circuit including at least a first block, a second block, and a first wiring for connecting a first output pin of the first block and a first input pin of the second block, the method comprises the steps of: a step for arranging a first block and a second block; a step for wiring a first output pin of the first block and a first input pin of the second block with a first wiring including a wiring portion of a predetermined angle of approximately 45 degrees at least one part; a step for arranging a third bock including at least a set of input pin and an output pin lined in alignment in the X direction or the Y direction between the first block and the second block at a predetermined angle of approximately 45 degrees; and a step for connecting a cell of the third block to the wiring portion of a predetermined angle of approximately 45 degrees in the first wiring.

A method of designing a semiconductor integrated circuit of the present invention relates to a method of designing the semiconductor integrated circuit including at least a first block, a second block, and a first wiring for connecting a first output pin of the first block and a first input pin of the second block, the method comprises the steps of: a step for arranging a first block and a second block; wiring a first output pin of the first block and a first input pin of the second block with a first wiring including a wiring portion of a predetermined angle of approximately 45 degrees at least one part thereof; a step for arranging a third bock including at least a set of input pin and an output pin arranged in a straight line of a predetermined angle of approximately 45 degrees between the first block and the second block; and a step for connecting a cell of the third block to the wiring portion of a predetermined angle of approximately 45 degrees in the first wiring.

Furthermore, in the step of arranging the third block, it is included that the third block is arranged at a position where the input pin and the output pin of the cell overlap to the wiring portion of the predetermined angle of approximately 45 degrees.

In the above designing method, the case is included that a buffer is used as the cell.

Herewith, since the wiring is not restricted to the X, Y directions before inserting the repeater cell and the like, the wiring length can be reduced in advance. Furthermore, the change in wiring at the time of inserting the repeater cell is suppressed to a minimum by arranging the input pin and the output pin of the repeater cell in alignment in the direction of the tilted wiring.

### EFFECTS OF THE INVENTION

According to the present invention, the tilted wiring is used effectively, the wiring length is reduced, and higher integration of the semiconductor integrated circuit is achieved.

### BRIEF DESCRIPTION OF THE DRAWINGS

FIG. 1 is a layout view of a semiconductor integrated circuit in a first embodiment of the present invention.

FIG. 2 is an enlarged view of the layout view of FIG. 1.

FIG. 3 is a design flow of a semiconductor integrated circuit in a second embodiment of the present invention.

FIG. 4 is a layout view of the semiconductor integrated circuit in the second embodiment of the present invention.

FIG. 5 is a layout view of a repeater cell (repeater buffer) in the second embodiment of the present invention.

FIG. 6 is a layout view of after insertion of a repeater buffer in the second embodiment of the present invention.

FIG. 7 is a layout view of after re-wiring in the second embodiment of the present invention.

FIG. 8 is a layout view of a repeater cell (repeater buffer) according to a third embodiment of the present invention.

FIG. 9 is a layout view of after insertion of a repeater buffer in the third embodiment of the present invention.

FIG. 10 is a layout view of after re-wiring in the third embodiment of the present invention.

FIG. 11 is a layout view of a semiconductor integrated circuit according to the prior art.

FIG. 12 is an explanatory view of a wiring grid of a tilted wiring according to the prior art.

FIG. 13 is a view explaining the method of inserting a repeater cell according to the prior art.

### DESCRIPTION OF SYMBOLS

B1-B4 block
B5 and B15 repeater buffer
L1-L7, L11, and L12 wiring
P1-P4 pin
Q1-Q4, Q11, and Q12 input/output pin
S1 arrangement step
S2 wiring step
S3 repeater arrangement step
S4 re-wiring step

### BEST EMBODIMENT FOR CARRYING OUT THE INVENTION

### First Embodiment

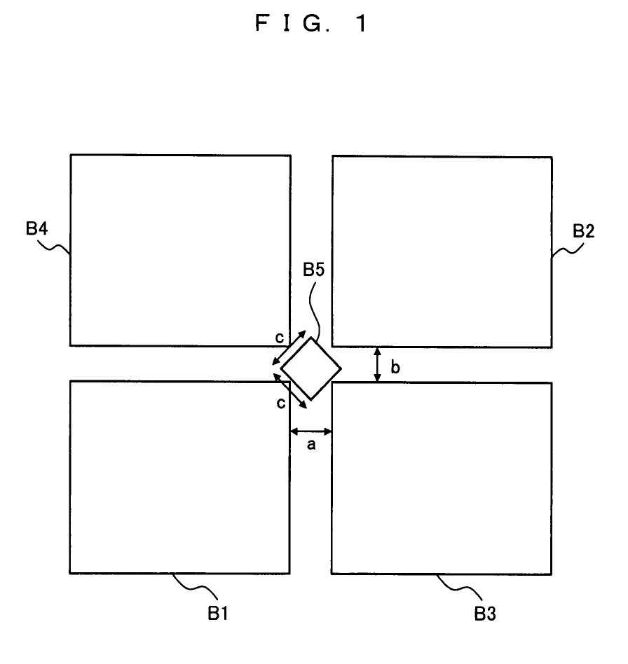

FIG. 1 is a layout view showing the block arrangement of a semiconductor integrated circuit in a first embodiment of the present invention. In FIG. 1, B1 to B5 are blocks, where blocks B1 to B4 are arranged in two lines vertically and horizontally at a spacing of a in the X direction and b in the Y direction. The length of one side of block B5 is c. The length c satisfies the relationship c<√(a2+b2). The block B5. is diagonally arranged at 45 degrees to the blocks B1 to B4 at the central part where the blocks B1 to B4 are arranged. The tilted orientation of exactly 45 degrees is preferable, but is not essential, and merely needs to be a predetermined angle of approximately 45 degrees.

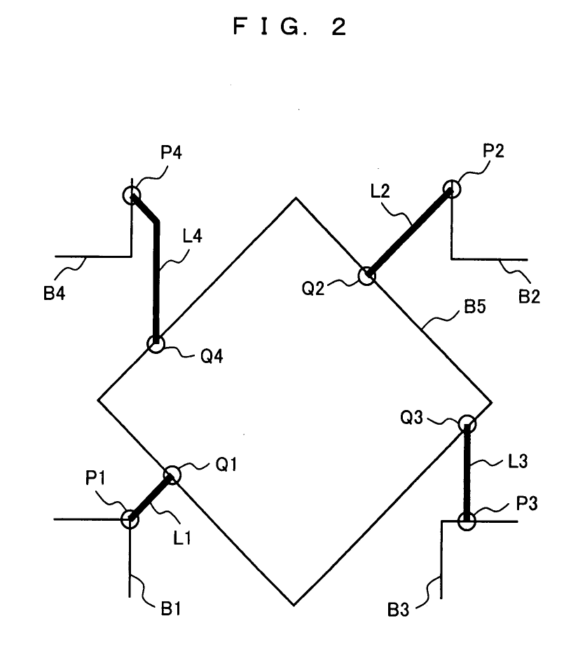

FIG. 2 is an enlarged view of the vicinity of the block B5 in FIG. 1. In FIG. 2, P1 to P4 are respectively pins of the blocks B1 to B4, and Q1 to Q4 are pins of the block B5. L1 to L4 are wirings connecting between the pins of the blocks, where the wiring L1 connects pins P1 and Q1; the wiring L2 connects pins P2 and Q2; the wiring L3 connects pins P3 and Q3; and the wiring L4 connects pins P4 and Q4. The tilted wiring is used partially or entirely in the wirings L1, L2, L4. Which wiring layer each wiring is using is not illustrated as it is not essential in the present invention. Based on the same reason, a contact hole for switching between the wiring layers is also not illustrated. In FIG. 2, the pins of the blocks B1 to B5 may be other than those shown. The wirings between the blocks may be other than those shown.

The operation of the semiconductor integrated circuit of the first embodiment configured as mentioned above will now be described.

The blocks B1 to B4 are arranged apart by distance a in the horizontal direction and distance b in the vertical direction.

As exemplified in FIG. 11, the block B5 having the length of one side of c is arranged along the X and Y directions between the blocks B1 to B4 in the prior art. In this case, the block B5 cannot be arranged if the arrangement of the blocks B1 to B4 is the same as in FIG. 1. The blocks B1 to B4 must be moved to secure a region for arranging the block B5. The distance d between the blocks B2 and B3 after the block B2 is moved upward satisfies the relationship d>c. As a result, the area of the entire arrangement region of the blocks B1 to B5 increases, so that the area of the semiconductor integrated circuit also increases.

On the contrary, in the present embodiment shown in FIG. 1, the degree of freedom of block arrangement increases by arranging the block B5 in a tilted manner, whereby the arrangement is realized without extending the region between the blocks B1 to B4, and higher integration is achieved. Furthermore, in arranging the block B5, arrangement is made in view of using the tilted wiring so that the wiring length of the wirings L1 to L4 becomes shorter, and the wiring length is reduced through performing the tilted wiring after the arrangement.

### Second Embodiment

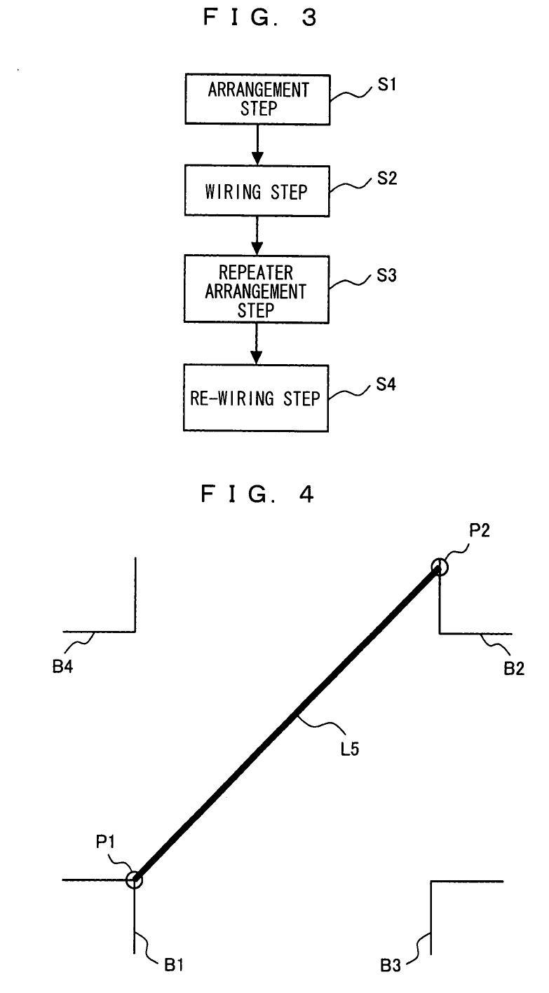

FIG. 3 is a diagram of the design flow of the semiconductor integrated circuit according to a second embodiment of the present invention. In FIG. 3, S1 is an arrangement step for arranging the blocks, S2 is a wiring step for wiring between the blocks, S3 is a repeater arrangement step of arranging the repeater, and S4 is a re-wiring step of performing wiring on the arranged repeater.

FIG. 4 is a layout view of the semiconductor integrated circuit after the arrangement step S1 and the wiring step S2 of FIG. 3 are completed. The pin P1 of the block B1 and the pin P2 of the block B2 are connected through the tilted wiring L5.

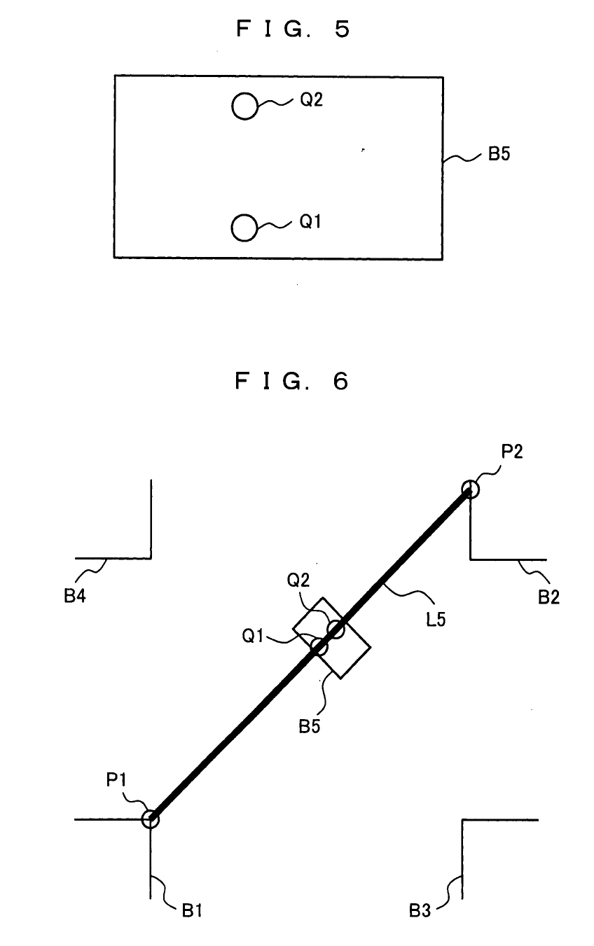

FIG. 5 is a layout view of the repeater cell B5 arranged in the repeater arrangement step S3. The repeater cell B5 has a function of a buffer. The repeater cell is hereinafter referred to as repeater buffer B5. Q1 and Q2 are input/output pins. The input/output pins Q1 and Q2 are lined in alignment in the Y direction in the repeater buffer B5. The pins may be lined in alignment in the X direction. Two or more input/output pins Q1 and Q2 may be arranged respectively. Transistors and other wirings etc. also exist in the repeater buffer B5, but are omitted in FIG. 5.

FIG. 6 is a layout view of the semiconductor integrated circuit after the repeater arrangement step S3 is completed. The repeater buffer B5 is arranged at a tilted orientation of 45 degrees so that the input/output pins Q1 and Q2 of the repeater buffer B5 correspond in position to the tilted wiring L5.

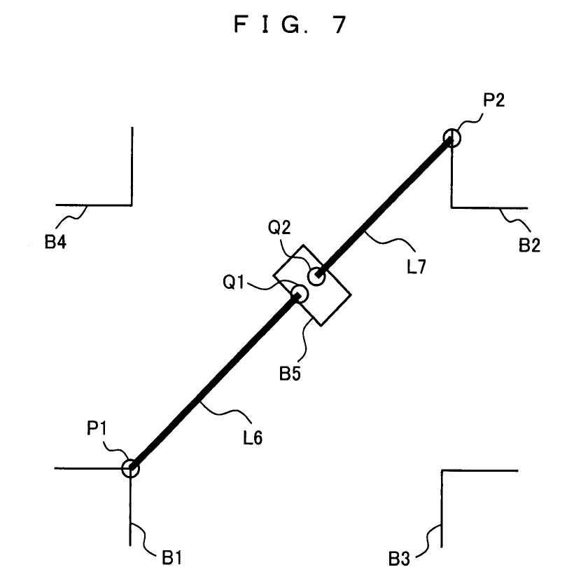

FIG. 7 is a layout view of the semiconductor integrated circuit after the re-wiring step S4 is competed. The wiring L5 is cut into wirings L6 and L7, where the pin P1 of the block B1 and the input/output Q1 of the repeater buffer B5 are connected by the wiring L6, and the pin P2 of the block B2 and the input/output pin Q2 of the repeater buffer B5 are connected by the wiring L7. In correspondence to the description of the Claims, P1 corresponds to the first output pin, Q1 corresponds to the second input pin, Q2 corresponds to the second output pin, and P2 corresponds to the first input pin. The wiring L6 and the wiring L7 are arranged at an angle of 45 degrees, and are on the same straight line.

The operation of the method of designing the semiconductor integrated circuit of the second embodiment configured as above will be described below.

First, the arrangement of the blocks and the wiring of the blocks are performed according to the arrangement step S1 and the wiring step S2 of the blocks. In the wiring step S2, wiring is performed using also the titled wiring. The layout after the wiring step S2 is completed is shown in FIG. 4, where the pins P1, P2 are wired by the tilted wiring L5 of a straight line.

Subsequently, it is necessary that the repeater buffer B5 is inserted in the wiring L5 if the delay value in the wiring L5 is large. Consequently, the arrangement of the repeater buffer B5 is performed in the repeater arrangement step S3. As shown in FIG. 5, the input/output pins Q1 and Q2 of the repeater buffer B5 are lined in alignment in the Y direction. The repeater buffer B5 is rotated 45 degrees in the clockwise direction to be arranged in a tilted manner, as shown in FIG. 6. Herewith, the input/output pins Q1, Q2 are lined in alignment in the diagonal direction so as to overlap the wiring L5.

Next, in the re-wiring step S4, cutting of the wiring L5 where the repeater buffer B5 is inserted, and re-connection to the repeater buffer B5 are performed. The wiring L5 is cut between the input/output pins Q1, Q2 to be divided into wirings L6 and L7, as shown in FIG. 7. The wiring L6 is connected to the input/output pin Q1 and the wiring L7 is connected to the input/output pin Q2.

The change in wiring before and after insertion of the repeater buffer B5 can be suppressed small according to the method of designing the semiconductor integrated circuit described above. The circumvention of the wirings connected to the input/output pins Q1, Q2 of the repeater buffer B5 is avoided, and even if wirings are present around the wiring L5, the influence on such wirings is suppressed to a minimum. Therefore, in addition to easiness in the insertion of the repeater buffer B5, the wiring length to the repeater buffer B5 can be minimized. Further, the number of necessary repeaters to be inserted can be reduced compared to the prior art since the tilted wiring is used from the arrangement step S2.

The tilt angle of 45 degrees for the wirings L5, L6, L7 and the repeater buffer B5 is a preferable example, but is not essential, and merely needs to be a predetermined angle of approximately 45 degrees.

### Third Embodiment

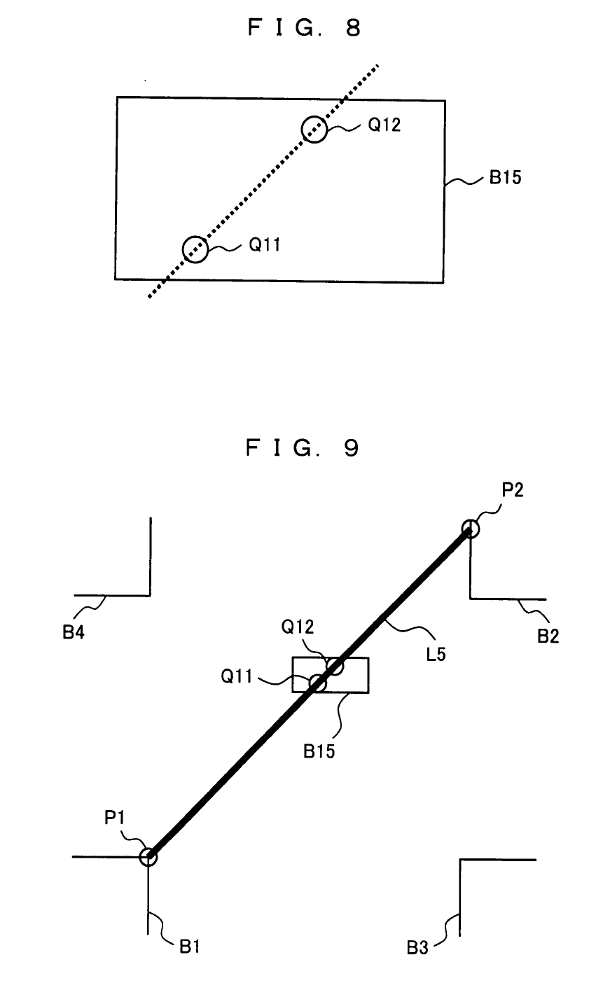

The design flow of the semiconductor integrated circuit of the third embodiment is the same as the design flow of the semiconductor integrated circuit of the second embodiment, and is as shown in FIG. 3. FIG. 8 is a layout view of the repeater cell arranged in the repeater arrangement step S3 in the design flow of the semiconductor integrated circuit of the third embodiment. The repeater cell B15 has a function of a buffer. The repeater cell B15 is hereinafter referred to as repeater buffer B15. Q11 and Q12 are input/output pins of the repeater buffer 15, and are arranged on a straight line forming 45 degrees to the visible outline of the repeater buffer B15. That is, the input/output pins Q11, Q12 are lined in alignment on a parallel with the tilted wiring (shown in dotted line in FIG. 8). Transistors and other wirings are also present in the repeater buffer B15, but are omitted in FIG. 8.

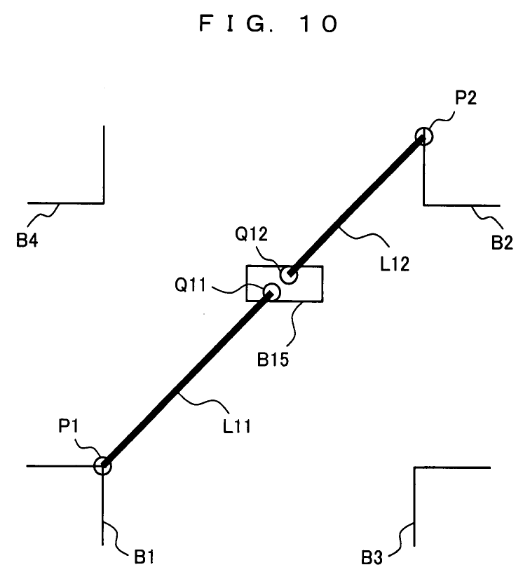

FIG. 9 is a layout view of the semiconductor integrated circuit after the repeater arrangement step S3 is completed with respect to the semiconductor integrated circuit of FIG. 4. In FIG. 9, the same reference numbers are given to the same components as in FIG. 4. The repeater buffer B15 is arranged without changing the orientation thereof, and the input/output pins Q11, Q12 lined on a straight line of 45 degrees are overlapped on the tilted wiring L5.

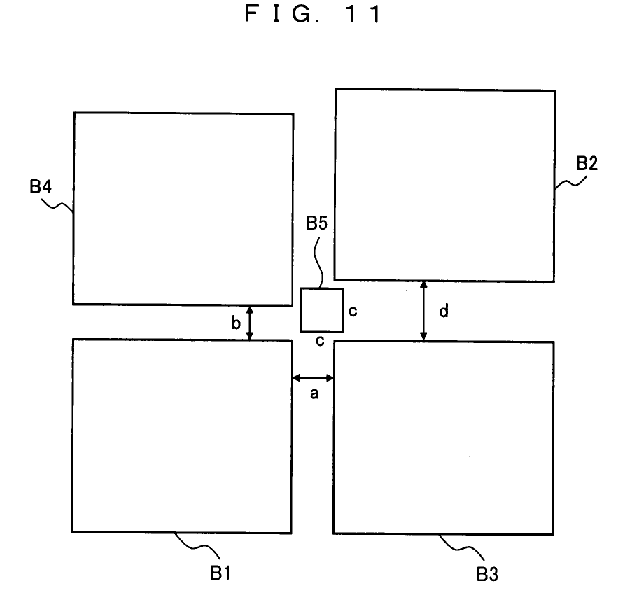

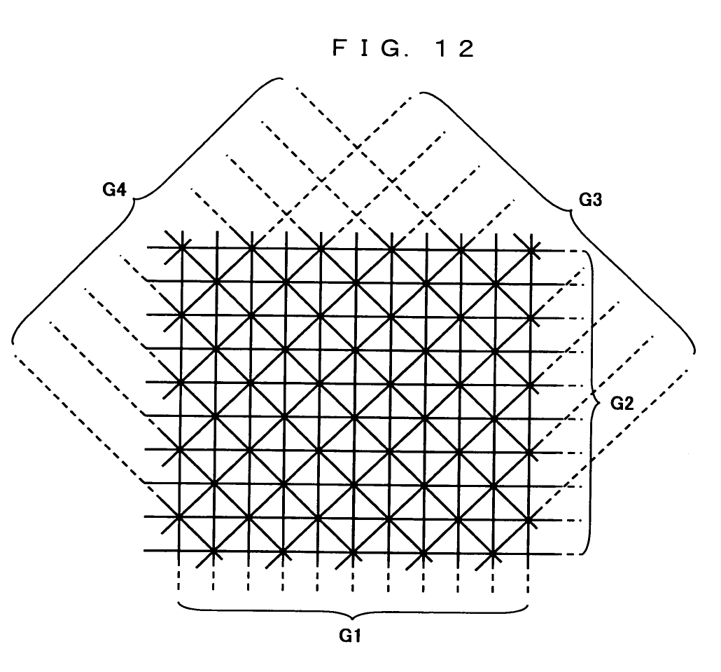

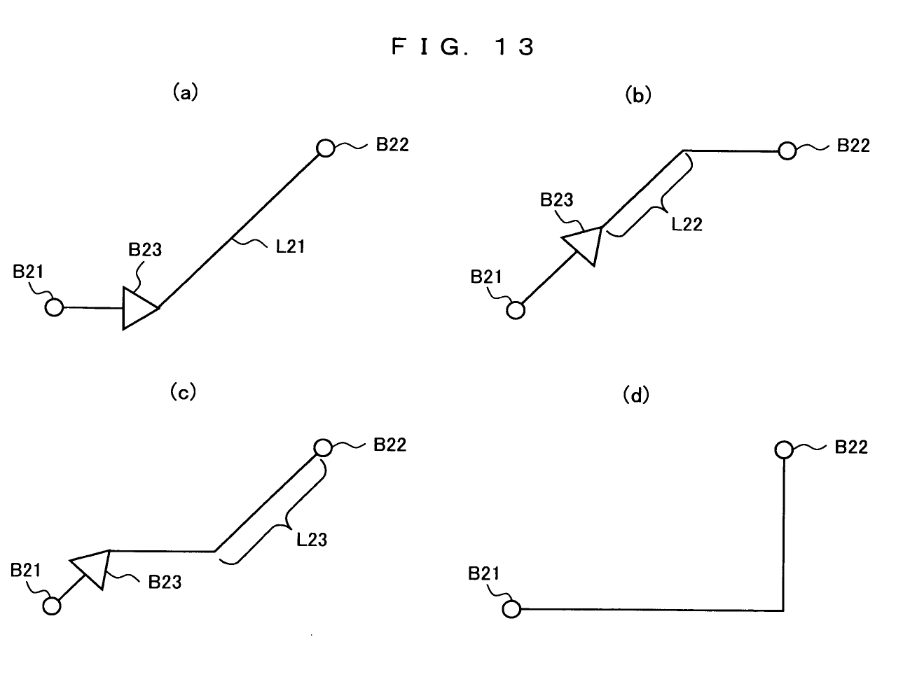

FIG. 10 is a layout view of the semiconductor integrated circuit after the re-wiring step S4 is completed. The wiring L5 is cut into wirings L11 and L12, where the pin P1 of the block B1 and the input/output pin Q11 of the repeater buffer B15 are connected by the wiring L11, and the pin P2 of the block B2 and the input/output pin Q12 of the repeater buffer B15 are connected by the wiring L12. In correspondence to the description of the Claims, P1 corresponds to the first output pin Q12, Q11 corresponds to the second input pin, Q12 corresponds to the second output pin and P2 corresponds to the first input pin.

The operation of the method of designing the semiconductor integrated circuit of the third embodiment configured as above will be described below.

Steps up to the wiring step S2 are the same as the second embodiment. Thereafter, the repeater buffer B15 must be inserted in the wiring L5 if the delay value in the wiring L5 is large, in similar fashion to the second embodiment. The arrangement of the repeater buffer B15 is performed in the repeater arrangement step S3. The input/output pins Q1 and Q2 of the repeater buffer B15 are lined in alignment in the diagonal direction from the beginning, as shown in FIG. 8. Therefore, the repeater buffer B15 is arranged in such orientation without being rotated, and the input/output pins Q11, Q12 overlap the wiring L5.

Then, in the re-wiring step S4, cutting of the wiring L5 where the repeater buffer B15 is inserted and re-connection to the repeater buffer B15 are performed. The wiring L5 is cut between the input/output pins Q11, Q12 to be divided into wirings L11 and L12, as shown in FIG. 10. And then, the wiring L11 is connected to the input/output pin Q11 and the wiring L12 is connected to the input/output pin Q12.

The change in wiring before and after the insertion of the repeater buffer B15 can be suppressed small according to such method of designing the semiconductor integrated circuit. The circumvention of the wirings connected to the input/output pins Q11, Q12 of the repeater buffer B15 is avoided, and even if wirings are present around the wiring L5, the influence on such wirings is suppressed to a minimum. Therefore, in addition to easiness in the insertion of the repeater buffer B15, the wiring length to the repeater buffer B5 can be minimized. The number of necessary repeaters to be inserted can be reduced compared to the prior art since the tilted wiring is used from the arrangement step S2.

Furthermore, the cell is inserted as the insertion of the repeater buffer in the second and third embodiments of the present invention, but a block including the repeater buffer may be inserted. Additionally, instead of inserting the repeater buffer, an arbitrary logic cell (e.g., inverter, AND gate etc.) or a block including the cell may be inserted. If the total number of input/output pins is three or more as in the AND gate, the pins connected to the wiring to which the cell is inserted, out of the pins of the cell to be inserted, merely need to overlap the wiring.

The tilt angle of 45 degrees for the wirings L5, L11 and L2, and the repeater buffer B15 is a preferable example, but is not essential, and merely needs to be a predetermined angle of approximately 45 degrees.

### INDUSTRIAL APPLICABILITY

The present invention has features of using the tilted wiring more effectively, reducing the wiring length, and achieving higher integration and the like, and is useful as a semiconductor integrated circuit that achieves higher integration, higher performance etc. by smaller area.

1. A semiconductor integrated circuit consisting of a first block, a second block and a third block at least, wherein
the third block is diagonally arranged between the first block and the second block at a predetermined angle of approximately 45 degrees to the first block and the second block.

2. The semiconductor integrated circuit according to claim 1, wherein
the first block includes at least a first output pin,
the second block includes at least a first input pin,
the third block includes at least a second input pin and a second output pin,
the first output pin and the second input pin are connected by a first wiring, and
the second output pin and the first input pin are connected by a second wiring.

3. The semiconductor integrated circuit according to claim 2, wherein at least a part of the first wiring and the second wiring includes a wiring portion having a predetermined angle of approximately 45 degrees.

4. The semiconductor integrated circuit according to claim 3, wherein the first wiring and the second wiring are made up of a substantially straight wiring.

5. The semiconductor integrated circuit according to claim 4, wherein the first wiring and the second wiring are on the same straight line.

6. The semiconductor integrated circuit according to claim 2, wherein
the third block includes at least one cell,
the second input pin is connected to an input pin of the cell, and
the second output pin is connected to an output pin of the cell.

7. The semiconductor integrated circuit according to claim 6, wherein the cell is a buffer.

8. The semiconductor integrated circuit according to claim 6, wherein the cell includes at least one input pin and one output pin, where the input pin and the output pin are lined in alignment in the X direction or the Y direction.

9. The semiconductor integrated circuit according to claim 6, wherein the cell includes at least one input pin and one output pin, where the input pin and the output pin are arranged on a straight line having a predetermined angle of approximately 45 degrees.

10. A semiconductor integrated circuit configured by at least a first block, a second block, and a third block; wherein
the third block is arranged between the first block and the second block; and
the third block includes the cell described in claim 9.

11. The semiconductor integrated circuit according to claim 10, wherein
the first block includes at least a first output pin,
the second block includes at least a first input pin,
the third block includes at least a second input pin and a second output pin,
the first output pin and the second input pin are connected by a first wiring,
the second output pin and the first input pin are connected by a second wiring,
the second input pin is connected to the input pin of the cell, and
the second output pin is connected to the output pin of the cell.

12. The semiconductor integrated circuit according to claim 11, wherein each of the first wiring and the second wiring is made up of a straight wiring having a predetermined angle of approximately 45 degrees.

13. A cell comprising at least one input pin and one output pin, wherein the input pin and the output pin are lined in alignment in the X direction or the Y direction.

14. A cell comprising at least one input pin and one output pin, wherein the input pin and the output pin are arranged on a straight line having a predetermined angle of approximately 45 degrees.

15. A method of designing a semiconductor integrated circuit, the method comprising the steps of:
a step for arranging a first block and a second block;
a step for wiring a first output pin of the first block and a first input pin of the second block with a first wiring including a wiring portion of a predetermined angle of approximately 45 degrees at least a part thereof;
a step for arranging a third bock including at least a set of input pin and an output pin lined in alignment in the X direction or the Y direction between the first block and the second block at a predetermined angle of approximately 45 degrees; and
a step for connecting a cell of the third block to the wiring portion of a predetermined angle of approximately 45 degrees in the first wiring.

16. A method of designing a semiconductor integrated circuit, the method comprising the steps of:
a step for arranging a first block and a second block;
a step for wiring a first output pin of the first block and a first input pin of the second block with a first wiring including a wiring portion of a predetermined angle of approximately 45 degrees in at least a part thereof;
a step for arranging a third bock including at least a set of input pin and an output pin arranged in a straight line of a predetermined angle of approximately 45 degrees between the first block and the second block; and
a step for connecting a cell of the third block to the wiring portion of a predetermined angle of approximately 45 degrees in the first wiring.

17. The method of designing the semiconductor integrated circuit according to claim 15, wherein the third block is arranged at a position the input pin and the output pin of the cell overlap the wiring portion of the predetermined angle of approximately 45 degrees in a step for arranging the third block.

18. The method of designing the semiconductor integrated circuit according to claim 15, wherein a buffer is used as the cell.
